(19) United States
(12) Patent Application Publication
(10) Pub. No.: US 2024/0244894 A1
(43) Pub. Date: Jul. 18, 2024

(54) DISPLAY PANEL AND DISPLAY DEVICE

(71) Applicant: Visionox Technology Inc., Suzhou (CN)

(72) Inventors: Liusong NI, Suzhou (CN); Yiming XIAO, Suzhou (CN); Yuan YAO, Suzhou (CN); Xiujian ZHU, Suzhou (CN); Xuejing ZHU, Suzhou (CN); Bowen YANG, Suzhou (CN); Haohan ZHANG, Suzhou (CN)

(73) Assignee: Visionox Technology Inc., Suzhou (CN)

(21) Appl. No.: 18/623,394

(22) Filed: Apr. 1, 2024

Related U.S. Application Data
(63) Continuation-in-part of application No. PCT/CN2023/111234, filed on Aug. 4, 2023.

(30) Foreign Application Priority Data
Aug. 24, 2022 (CN) 202222231507.0

(51) Int. Cl. H10K 59/122; H10K 59/95

(52) U.S. Cl. CPC H10K 59/122; H10K 59/95

(57) ABSTRACT

A display panel and a display device. The display panel includes: a base plate; a planarization layer disposed on the base plate, the planarization layer includes a surface away from the base plate including a first partial surface and a plurality of second partial surfaces, and roughness of at least a part of the first partial surface is greater than roughness of the second partial surfaces; a pixel electrode layer disposed on a side of the planarization layer away from the base plate, the pixel electrode layer includes a plurality of pixel electrodes distributed in an array, and each of the pixel electrodes is located on a corresponding second partial surface; a pixel definition layer disposed on the side of the planarization layer away from the base plate.

### CROSS-REFERENCE TO RELATED APPLICATION

This application is a continuation-in-part application of International Application No. PCT/CN2023/111234, filed on Aug. 4, 2023, which claims priority to Chinese Patent Application No. 202222231507.0, filed on Aug. 24, 2022, all of which are hereby incorporated by reference in their entireties.

### TECHNICAL FIELD

The present application relates to a technical field of a display device, and particularly relates to a display panel and a display device.

### BACKGROUND

Organic light-emitting diodes (OLED) are active light-emitting devices. Compared with the display mode of the traditional liquid crystal display (LCD), the OLED display technology does not need a backlight and has the characteristic of self-light-emitting. The OLED includes a thin film layer of organic material and a glass substrate, and the organic material emits light when an electric current passes through it. Therefore, the OLED display panel can significantly save power, can be made lighter and thinner, can tolerate a wider range of temperature changes than the LCD display panel, and can have a larger viewing angle. The OLED display panel is expected to become the next generation of flat panel display technology after LCD, and is one of the most concerned technologies in the current flat panel display technology. However, the current OLED display technology has a problem of low yield.

### SUMMARY

The embodiments of the present application provide a display panel and a display device, which can improve the yield of the display panel.

The embodiments of a first aspect of the present application provide a display panel, including: a base plate; a planarization layer disposed on the base plate, wherein the planarization layer includes a surface away from the base plate including a first partial surface and a plurality of second partial surfaces, and roughness of at least a part of the first partial surface is greater than roughness of the second partial surfaces; a pixel electrode layer disposed on a side of the planarization layer away from the base plate, wherein the pixel electrode layer includes a plurality of pixel electrodes distributed in an array, and each of the pixel electrodes is located on a corresponding second partial surface; a pixel definition layer disposed on the side of the planarization layer away from the base plate, wherein the pixel definition layer includes an isolation portion and a pixel opening enclosed by the isolation portion, the pixel electrode is exposed by the pixel opening, and at least a part of the isolation portion is located on the first partial surface.

The embodiments of a second aspect of the present application provide a display device, including the display panel in any of the above embodiments.

In the display panel provided by the present application, the display panel includes the base plate as well as the planarization layer, the pixel electrode layer and the pixel definition layer disposed on the base plate. The pixel electrodes of the pixel electrode layer and the isolation portion of the pixel definition layer are all disposed on the surface of the planarization layer away from the substrate, wherein the pixel electrodes are located on the second partial surfaces, and the isolation portion is located on the first partial surface. The roughness of the first partial surface is greater than the roughness of the second partial surfaces, which can improve the contact area between the isolation portion and the surface of the planarization layer, thereby improving the stability of the relative position between the isolation portion and the planarization layer. Further, the problem that the yield of the display panel is affected by the water and oxygen intruding into the pixel opening due to the easy detachment of the isolation portion from the planarization layer may be improved. Therefore, the present application can improve the yield of the display panel.

### BRIEF DESCRIPTION OF THE DRAWINGS

FIG. 1 is a local cross-sectional view of a display panel provided by an embodiment of a first aspect of the present application;

FIG. 2 is a local cross-sectional view of a display panel provided by another embodiment of the first aspect of the present application;

FIG. 3 is a local cross-sectional view of a display panel provided by another embodiment of the first aspect of the present application;

FIG. 4 is a local cross-sectional view of a display panel provided by another embodiment of the first aspect of the present application;

FIG. 5 is a local cross-sectional view of a display panel provided by another embodiment of the first aspect of the present application;

FIG. 6 is a local cross-sectional view of a display panel provided by another embodiment of the first aspect of the present application.

### DETAILED DESCRIPTION

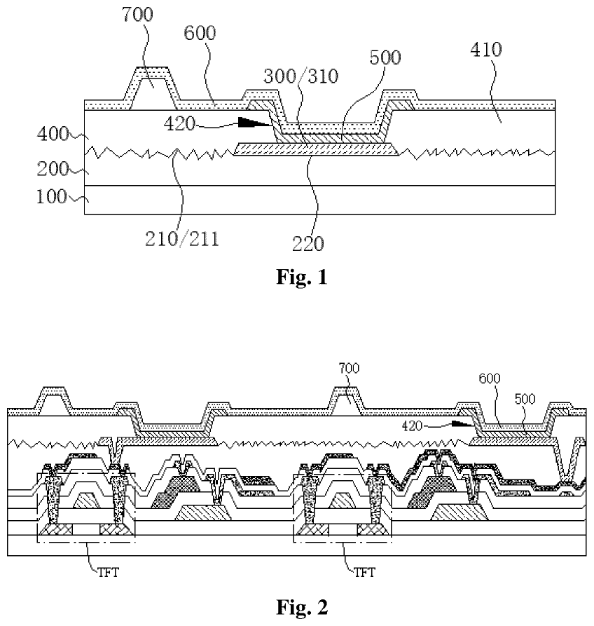

In order to better understand the present application, the display panel and the display device of the embodiments of the present application are described in detail below in combination with FIGS. 1 to 5.

FIG. 1 is a local cross-sectional view of a display panel provided by an embodiment of a first aspect of the present application.

As shown in FIG. 11, the display panel provided by the present application includes: a base plate 100; a planarization layer 200 disposed on the base plate 100, wherein the planarization layer 200 includes a surface away from the base plate 100, the surface includes a first partial surface 210 and a plurality of second partial surfaces 220, and roughness of at least a part of the first partial surface 210 is greater than roughness of the second partial surfaces 220; a pixel electrode layer 300 disposed on a side of the planarization layer 200 away from the base plate 100, wherein the pixel electrode layer 300 includes a plurality of pixel electrodes 310 distributed in an array, and each of the pixel electrodes 310 is located on a corresponding second partial surface 220; a pixel definition layer 400 disposed on the side of the planarization layer 200 away from the base plate 100, wherein the pixel definition layer 400 includes an isolation portion 410 and a pixel opening 420 enclosed by the isolation portion 410, the pixel electrode 310 is exposed by the pixel opening 420, and at least a part of the isolation portion 410 is located on the first partial surface 210.

In the display panel provided by the present application, the display panel includes the base plate 100 as well as the planarization layer 200, the pixel electrode layer 300 and the pixel definition layer 400 disposed on the base plate 100. The pixel electrodes 310 of the pixel electrode layer 300 and the isolation portion 410 of the pixel definition layer 400 are all disposed on the surface of the planarization layer 200 away from the substrate 100, wherein the pixel electrodes 310 are located on the second partial surfaces 220, and the isolation portion 410 is located on the first partial surface 210. The roughness of the first partial surface 210 is greater than the roughness of the second partial surfaces 220, which can improve the contact area between the isolation portion 410 and the surface of the planarization layer 200, thereby improving the stability of the relative position between the isolation portion 410 and the planarization layer 200. Further, the problem that the yield of the display panel is affected by the water and oxygen intruding into the pixel opening 420 due to the easy detachment of the isolation portion 410 from the planarization layer 200 may be improved. Therefore, the present application can improve the yield of the display panel.

Please refer to FIG. 2, FIG. 2 is a local cross-sectional view of a display panel provided by another embodiment of the first aspect of the present application.

The base plate 100 may be arranged in various ways. For example, as shown in FIG. 2, the base plate 100 includes a substrate and an array base plate disposed on the substrate. The array base plate 100 includes a driving circuit TFT and a signal line, and the driving circuit is connected to the pixel electrode 310.

Optionally, please continue to refer to FIG. 2, a light-emitting unit 500 is disposed within the pixel opening 420, and the display of the display panel is implemented through the light-emitting unit 500. The light-emitting unit 500 is connected with the pixel electrode 310 in the pixel opening 420, so that the pixel electrode 310 can drive the light-emitting unit 500 to emit light. The light-emitting unit 500 includes, for example, a red light-emitting unit 500, a green light-emitting unit 500, and a blue light-emitting unit 500.

Optionally, please continue to refer to FIG. 2, a common electrode layer 600 is further disposed on a side of the pixel definition layer 400 away from the base plate 100, and the common electrode layer 600 is used to interact with the pixel electrode 310 to drive the light-emitting unit 500 to emit light. Optionally, a support column 700 is further disposed on the pixel definition layer 400, the common electrode layer 600 is located on a side of the support column 700 away from the pixel definition layer 400, and the support column 700 is configured for supporting a cover plate of the display panel.

In the present application, it is only necessary that the roughness of at least a part of the first partial surface 210 is greater than the roughness of the second partial surfaces 220. The first partial surface 210 refers to a partial surface of the planarization layer 200 in contact with the isolation portion 410, and the second partial surface 220 refers to a partial surface of the planarization layer 200 in contact with the pixel electrode 310.

In some optional embodiments, please continue to refer to FIGS. 1 and 2, the first partial surface 210 is provided with a plurality of protrusions 211 distributed sequentially.

In these optional embodiments, by disposing the protrusions 211 on the first partial surface 210, the roughness of the first partial surface 210 can be increased, thereby improving the contact area between the planarization layer 200 and the isolation portion 410. Further, the problem that the yield of the display panel is affected by the water and oxygen intruding into the pixel opening 420 due to the easy detachment of the isolation portion 410 from the planarization layer 200 may be improved, and the yield of the display panel may be improved.

There are a variety of methods for forming the protrusions 211 on the first partial surface 210. For example, an interface passivation process may be performed on the first partial surface 210 by laser light, and the intensities of the laser light at different positions may be changed, thereby changing the etching depth of the laser light, and finally forming the plurality of protrusions 211.

The shape of the protrusion 211 may be varied, and the shape of the protrusion 211 may be a regular shape or an irregular shape. In some optional embodiments, the shape of the protrusion 211 is at least one of a hemispherical shape, a prismatic shape, a pyramid shape, and a combination thereof.

The number and the arrangement of the protrusions 211 may be varied. The plurality of protrusions 211 may be arranged in rows and columns, or the plurality of protrusions 211 may be arranged in an irregular pattern. The adjacent two protrusions 211 may be arranged adjacently, or the adjacent two protrusions 211 may be spaced apart from each other.

In some optional embodiments, a height difference between the protrusion 211 and the second partial surface 220 is 100 Å to 300 Å.

In these optional embodiments, under a condition that the height difference between the protrusion 211 and the second partial surface 220 is within the above range, the problem of the easy detachment of the isolation portion 410 from the planarization layer 200 caused by the small contact area between the isolation portion 410 and the planarization layer 200 due to the insufficient height of the protrusion 211 may be improved. Further, it is also possible to prevent the relative position of the isolation portion 410 and the pixel electrode 310 from being affected by the high height of the protrusion 211. For example, under a condition that the protrusion 211 is higher than the pixel electrode 310, the light-emitting unit 500 may not be able to fully contact the pixel electrode 310, which will affect the light-emitting efficiency of the display panel.

The material of the planarization layer 200 may be varied. For example, the material of the planarization layer 200 includes an inorganic material, which can effectively reduce the manufacturing cost of the display panel relative to the organic material of the planarization layer 200.

The material of the pixel definition layer 400 may be varied. For example, the material of the pixel definition layer 400 includes an organic material, which can improve the contact strength between the pixel definition layer 400 and the planarization layer 200.

Alternatively, the material of the pixel definition layer 400 includes an inorganic material. Because of the large roughness of the second partial surface 220 of the present application, even if the material of the pixel definition layer 400 includes the inorganic material, sufficient contact strength between the isolation layer 410 and the planarization layer 200 can be guaranteed.

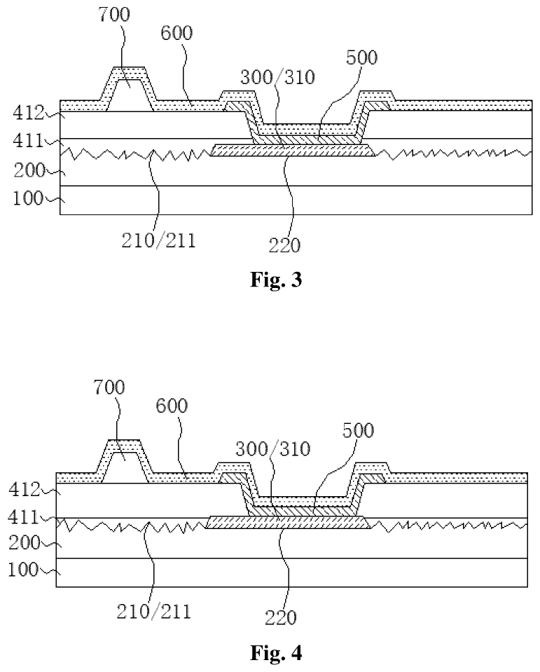

Referring to FIG. 3, FIG. 3 is a local cross-sectional view of a display panel provided by another embodiment of the first aspect of the present application.

In some optional embodiments, as shown in FIG. 3, the isolation portion 410 includes a first sub-layer 411 and a second sub-layer 412 distributed sequentially in a direction away from the planarization layer 200, the first sub-layer 411 and the second sub-layer 412 both include silicon, and the amount of silicon in the first sub-layer 411 is less than the amount of silicon in the second sub-layer 412.

In these optional embodiments, the first sub-layer 411 comprises SiN, and the second sub-layer 412 comprises at least one of SiO and SiON.

In these optional embodiments, the isolation portion 410 include stacked layers, the isolation portion 410 includes the first sub-layer 411 and the second sub-layer 412 that are stacked, and the amount of silicon in the first sub-layer 411 is small, thereby ensuring sufficient contact strength between the isolation portion 410 and the planarization layer 200, and improving the problem of easy detachment of the isolation portion 410.

In some optional embodiments, the thickness of the first sub-layer 411 is 800 Å to 1200 Å.

In some optional embodiments, the thickness of the first sub-layer 411 is greater than or equal to 2000 Å.

In some optional embodiments, the thickness of the first sub-layer 411 is 2500 Å to 5000 Å.

In these optional embodiments, under a condition that the thickness of the first sub-layer 411 is within the above range, it can not only improve the problem of the insufficient contact strength between the isolation portion 410 and the planarization layer 200 due to the small thickness of the first sub-layer 411, but also improve the problem of the function of the isolation portion 410 from being affected due to the excessive thickness of the first sub-layer 411.

The thicknesses of the first sub-layer 411 and the second sub-layer 412 may be arranged in various ways. For example, the thickness of the second sub-layer 412 is equal to the thickness of the first sub-layer 411. Alternatively, the thickness of the second sub-layer 412 is greater than the thickness of the first sub-layer 411, which can further improve the structural strength of the isolation portion 410.

The arrangement between the thickness of the first sub-layer 411 and the thickness of the pixel electrode 310 may be varied. In some optional embodiments, please continue to refer to FIG. 3, the thickness of the first sub-layer 411 is greater than the thickness of the pixel electrode 310, and a part of the first sub-layer 411 is located on a surface of the pixel electrode 310 away from the planarization layer 200.

In these optional embodiments, the thickness of the first sub-layer 411 is greater than the thickness of the pixel electrode 310, and the first sub-layer 411 can climb from the side of the pixel electrode 310 to the surface of the pixel electrode 310 away from the planarization layer 200, thereby increasing the connection area of the first sub-layer 411 and the pixel electrode 310.

Referring to FIG. 4, FIG. 4 is a local cross-sectional view of a display panel provided by another embodiment of the first aspect of the present application.

In some optional embodiments, as shown in FIG. 4, the thickness of the first sub-layer 411 is less than the thickness of the pixel electrode 310, and a part of the second sub-layer 412 is located on a surface of the pixel electrode 310 away from the planarization layer 200.

In these optional embodiments, the thickness of the first sub-layer 411 is small, and the second sub-layer 412 climbs from the side of the pixel electrode 310 to the surface of the pixel electrode 310 away from the planarization layer 200, thereby increasing the contact area of the second sub-layer 412 and the pixel electrode 310.

The second partial surface 220 may be arranged in a variety of ways, and the second partial surface 220 may also be a rough surface, thereby increasing the contact area of the pixel electrode 310 and the planarization layer 200, and improving the detachment problem of the pixel electrode 310.

Alternatively, the second partial surface 220 is a flat surface, which can reduce the usage of the material of the pixel electrode 310, thereby saving the material and the manufacturing cost of display panel. The second partial surface 220 being the flat surface does not mean that the second partial surface 220 is an absolute flat surface in the physical sense, but means that the second partial surface 220 is an approximate flat surface within the manufacturing tolerance range.

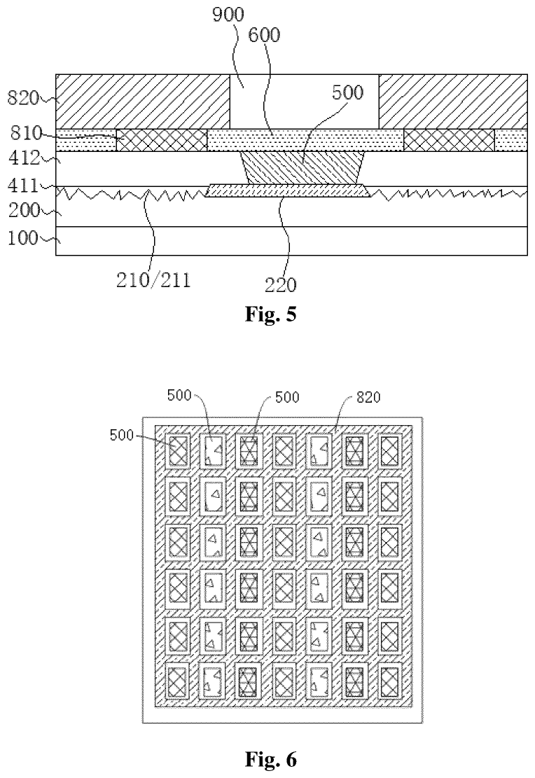

Referring to FIGS. 5 and 6, FIG. 5 is a local cross-sectional view of a display panel provided by another embodiment of the first aspect of the present application, and FIG. 6 is a local cross-sectional view of a display panel provided by another embodiment of the first aspect of the present application.

In some embodiments, the common electrode layer 600 includes a plurality of common electrodes, and each of the common electrodes is located on a side of a corresponding light-emitting unit 500 away from the pixel electrode 310. The display panel further includes a connection portion 810 located on the isolation portion 410 and configured for connecting adjacent common electrodes to each other, such that the plurality of common electrodes are interconnected as a surface electrode through the connection portion 810. The shape of the connection portion 810 may be a grid shape, and the common electrodes are located within grid openings of the connection portion 810.

Optionally, a raised portion 820 is disposed on a side of the connection portion 810 away from the isolation portion 410, and an area of an orthographic projection of the raised portion 820 on the planarization layer 200 is greater than an area of an orthographic projection of the connection portion 810 on the planarization layer 200, so that at least a part of the raised portion 820 can be suspended. Optionally, the display panel further includes an encapsulation portion 900 located within a space enclosed by the raised portion 820. Adjacent two encapsulation portions 900 are separated by the raised portion 820, thereby preventing the transfer of water vapor between the adjacent two encapsulation portions 900. Optionally, the display panel further includes an organic encapsulation layer and an inorganic encapsulation layer (not shown) disposed sequentially on a side of the encapsulation portion 900 away from the substrate 100.

The embodiments of a second aspect of the present application further provide a display device including the display panel described in any of the above embodiments in the first aspect. Since the display device provided by the embodiments of the second aspect of the present application includes the display panel described in any of the above embodiments in the first aspect, the display device provided by the embodiments of the second aspect of the present application has the beneficial effects of the display panel described in any of the above embodiments in the first aspect, which will not be repeated here.

An embodiment of the second aspect of the present application further provides a display device including a display panel of either of the above first aspect embodiments. Since the display device provided by the second aspect of the present application includes a display panel of any of the first aspects, the display device provided by the second aspect of the present application has the beneficial effect of the display panel of any of the first aspects will not be described here.

The display device in the embodiments of the present application includes, but is not limited to, a mobile phone, a personal digital assistant (PDA), a tablet computer, an e-book, a TV set, an entrance guard, a smart landline telephone, a console and other devices with display function.

Although the present application has been described with reference to the preferred embodiments, without departing from the scope of the present application, various improvements may be made and components may be replaced with equivalents. In particular, the various technical features mentioned in the respective embodiment can be combined in arbitrary ways as long as there is no structural conflict. The present application is not limited to the specific embodiments disclosed herein, but includes all technical schemes falling within the scope of the claims.

What is claimed is:

1. A display panel, comprising:
a base plate;
a planarization layer disposed on the base plate, wherein the planarization layer comprises a surface away from the base plate, the surface comprises a first partial surface and a plurality of second partial surfaces, and roughness of at least a part of the first partial surface is greater than roughness of the second partial surfaces;
a pixel electrode layer disposed on a side of the planarization layer away from the base plate, wherein the pixel electrode layer comprises a plurality of pixel electrodes distributed in an array, and each of the pixel electrodes is located on a corresponding second partial surface;
a pixel definition layer disposed on the side of the planarization layer away from the base plate, wherein the pixel definition layer comprises an isolation portion and a pixel opening enclosed by the isolation portion, the pixel electrode is exposed by the pixel opening, and at least a part of the isolation portion is located on the first partial surface.

2. The display panel according to claim 1, wherein the first partial surface is provided with a plurality of protrusions distributed sequentially.

3. The display panel according to claim 2, wherein a shape of the protrusion is at least one of a hemispherical shape, a prismatic shape, a pyramid shape, and a combination thereof.

4. The display panel according to claim 2, wherein a height difference between the protrusion and the second partial surface is 100 Å to 300 Å.

5. The display panel according to claim 1, wherein the isolation portion comprises a first sub-layer and a second sub-layer distributed sequentially in a direction away from the planarization layer, the first sub-layer and the second sub-layer both comprise silicon, and an amount of silicon in the first sub-layer is less than an amount of silicon in the second sub-layer.

6. The display panel according to claim 5, wherein the first sub-layer comprises SiN, and the second sub-layer comprises at least one of SiO and SiON.

7. The display panel according to claim 5, wherein a thickness of the first sub-layer is 800 Å to 1200 Å.

8. The display panel according to claim 5, wherein a thickness of the first sub-layer is greater than or equal to 2000 Å.

9. The display panel according to claim 8, wherein a thickness of the first sub-layer is 2500 Å to 5000 Å.

10. The display panel according to claim 5, wherein a thickness of the first sub-layer is greater than a thickness of the pixel electrode, and a part of the first sub-layer is located on a surface of the pixel electrode away from the planarization layer.

11. The display panel according to claim 5, wherein a thickness of the first sub-layer is less than a thickness of the pixel electrode, and a part of the second sub-layer is located on a surface of the pixel electrode away from the planarization layer.

12. The display panel according to claim 1, wherein the second partial surface is a flat surface.

13. The display panel according to claim 1, wherein a common electrode layer is further disposed on a side of the pixel definition layer away from the base plate.

14. The display panel according to claim 13, wherein a support column is further disposed on the pixel definition layer, the common electrode layer is located on a side of the support column away from the pixel definition layer, and the support column is configured for supporting a cover plate of the display panel.

15. The display panel according to claim 13, wherein the common electrode layer comprises a plurality of common electrodes, a light-emitting unit is disposed within the pixel opening, and each of the common electrodes is located on a side of a corresponding light-emitting unit away from the pixel electrode.

16. The display panel according to claim 15, wherein the display panel further comprises a connection portion located on the isolation portion and configured for connecting adjacent common electrodes to each other.

17. The display panel according to claim 16, wherein a shape of the connection portion is a grid shape, and the common electrodes are located within grid openings of the connection portion.

18. The display panel according to claim 16, wherein a raised portion is disposed on a side of the connection portion away from the isolation portion, and an area of an orthographic projection of the raised portion on the planarization layer is greater than an area of an orthographic projection of the connection portion on the planarization layer.

19. The display panel according to claim 18, wherein the display panel further comprises an encapsulation portion located within a space enclosed by the raised portion.

20. A display device comprising the display panel according to claim 1.
